(19) United States
(12) Patent Application Publication
(10) Pub. No.: US 2008/0153208 A1
(43) Pub. Date: Jun. 26, 2008

(54) Semiconductor Package Block Mold and Method

(76) Inventor: Akira Matsunami, Beppu (JP)

Correspondence Address: TEXAS INSTRUMENTS INCORPORATED, P O BOX 655474, M/S 3999, DALLAS, TX, 75265, US

(21) Appl. No.: 11/622,002

(22) Filed: Jan. 11, 2007

Related U.S. Application Data
(60) Provisional application No. 60/871,461, filed on Dec. 22, 2006.

(51) Int. Cl. H01L 21/56; H01L 21/78

(52) U.S. Cl. 438/112; 29/841; 438/113; 257/E21.502; 257/E21.599

(57) ABSTRACT

Semiconductor device packages and methods related to their manufacture are described in which improved block molds and block-molding methods alleviate warpage in semiconductor device manufacturing processes. Preferred embodiments of the invention are disclosed in which semiconductor device package manufacturing includes placing an array of chips mounted on a substrate within a mold. The mold is configured for encapsulating the chip and substrate array, and has features for excluding mold compound from selected areas to form ditches in the cured mold compound. The ditches act to reduce warpage. After removal from the mold, the block-molded array is singulated into individual semiconductor device packages.

### PRIORITY ENTITLEMENT

This application claims priority based on Provisional Patent Application Ser. No. 60/871,461 filed on Dec. 22, 2006, which is incorporated herein for all purposes by this reference. This application and the Provisional Patent Application have a common inventor and are assigned to the same entity.

### TECHNICAL FIELD

The invention relates to electronic semiconductor devices and manufacturing. More particularly, the invention relates to microelectronic semiconductor device packages and to block molds and block-molding methods for semiconductor package manufacturing.

### BACKGROUND OF THE INVENTION

Semiconductor devices are constructed from a semiconductor material wafer through a process that includes a number of steps leading to the production of individual chips suitable for packaging. It is common to mount a chip on a leadframe or laminated substrate providing a number of electrical contacts. Each chip also has contacts, which are then individually connected to the substrate contacts. The assemblies are completed by encapsulating them in molded resin, plastic, or ceramic packages that provide protection from hostile environments and yet enable electrical interconnection between the integrated circuit chip and an outside assembly such as a printed circuit board (PCB) or motherboard. In general, the elements of such a package include a substrate, an integrated circuit chip, bonding material to attach the integrated circuit chip to the substrate, electrical couplings between the integrated circuit chip and the substrate, and a hard encapsulant material, which covers and protects the other components and forms the exterior of the package.

For purposes of high-volume, low-cost production of IC packages, one current industry practice is to prepare a substrate in the form of a panel or strip which defines multiple chip mounting locations arranged in one or more arrays. In a typical chip package manufacturing process, the integrated circuit chips are mounted to respective locations in the arrays, with encapsulant material then applied to the array so as to collectively encapsulate all of the integrated circuit chips, bond wires, substrates, etc. This is how “block-molded” semiconductor packages, wherein numerous chips on a strip or array are encapsulated within a single molded body, are fabricated. Subsequent to the curing of the encapsulant, the block-molded arrays and their associated chips, substrates, and leads, are then cut apart, or singulated, for purposes of producing the individual chip packages. One common technique by which singulation is typically accomplished is a saw singulation process. In this process, the array of block-molded devices is secured on a cutting table while a saw blade is advanced along “saw streets” which extend in prescribed patterns between the block-molded chips as required to facilitate the separation of the packaged chips from one another for individual use.

Progress in integrated circuit technology continues to lead to higher and higher levels of circuit integration. This is a result of a relentless drive toward higher performance, lower cost, increased miniaturization of components, and greater package density. These attributes place high demands on the processes used to produce the individual semiconductor packages. Block-molding technologies and techniques encounter problems in the present state of the art. For example, block-molded arrays of chips sometimes warp due to internal mechanical stresses, or due to shrinkage of the mold compound during curing. Warpage can occur in the “corners up” direction, “corners down” direction, or in a combination of directions. This warpage can cause difficulties, particularly for saw singulation and ball attach processes. During saw singulation, warpage of the block-molded package arrays can result in the vacuum chuck, or other device used to secure the block-molded array for cutting, losing its ability to hold down the array. This can lead to the movement of the array during sawing. In current manufacturing processes, the loss of vacuum resulting from warpage requires the immediate interruption of singulation so that the array can be re-secured. Such interruptions are inefficient and costly. Warped block-molded arrays are also less suitable for ball attachment due to their non-planar surfaces, which may inhibit receiving balls, which are arranged in a planar grid. Solutions to these problems have been sought, but prior developments have neither taught nor suggested complete solutions, thus new solutions for addressing these problems would be useful and advantageous contributions to the arts.

### SUMMARY OF THE INVENTION

In carrying out the principles of the present invention, in accordance with preferred embodiments thereof, improved block molds and methods for block-molding reduce or eliminate problems associated with warpage.

According to one aspect of the invention, a method for manufacturing block-molded semiconductor device packages includes steps of placing a prepared array of chips mounted on a substrate into a mold. The mold is configured for encapsulating the chip and substrate array and for excluding mold compound from selected areas. By introducing mold compound into the mold and curing it, the chip and substrate array are encapsulated. A block-molded array thus formed has ditches formed by the exclusion of mold compound from selected areas. The mold is removed and individual semiconductor device packages are singulated from the block-molded array.

According to another aspect of the invention, preferred methods include the provision of a chip and substrate array having saw streets, and steps include the formation of at least some of the ditches in vertical alignment with at least some of the saw streets.

According to yet another aspect of the invention, singulation steps employ saw singulation.

According to another aspect of the invention, preferred embodiments include a block mold for semiconductor device package manufacturing. The block mold has a base configured for supporting an array of chips mounted on a substrate and also includes a cap configured for encapsulating the chip and substrate array. The cap has projections designed for excluding mold compound from selected areas at the surface of the package.

According to still another aspect of the invention, a preferred embodiment of a block mold includes projections arranged in a grid pattern on the surface of the cap.

According to another aspect of the invention, in representative preferred embodiments, a block mold cap includes projections arranged to coincide with saw streets of the chip and substrate array.

The invention has advantages including but not limited to providing methods and devices offering one or more of the following; alleviating tensile stress in cured mold compound used in block-molding processes, increased efficiency in singulation and ball attachment processes, and reduced costs. The features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1A is a simplified cutaway side view showing an example of initial steps in preferred embodiments of methods of the invention;

FIG. 1B is a simplified cutaway side view depicting intermediate steps in preferred embodiments of methods of the invention;

FIG. 1C is a simplified cutaway side view showing examples of further steps and completed packages according to preferred embodiments of the invention;

FIG. 2 is a top view of an example of a block-molded array of microelectronic semiconductor devices according to preferred embodiments of the invention; and

FIG. 3 is a top view of an example of a block-molded array of microelectronic semiconductor devices according to alternative preferred embodiments of the invention.

References in the detailed description correspond to like references in the various Figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides improved molds and block-molding methods for alleviating warpage during semiconductor device package manufacturing.

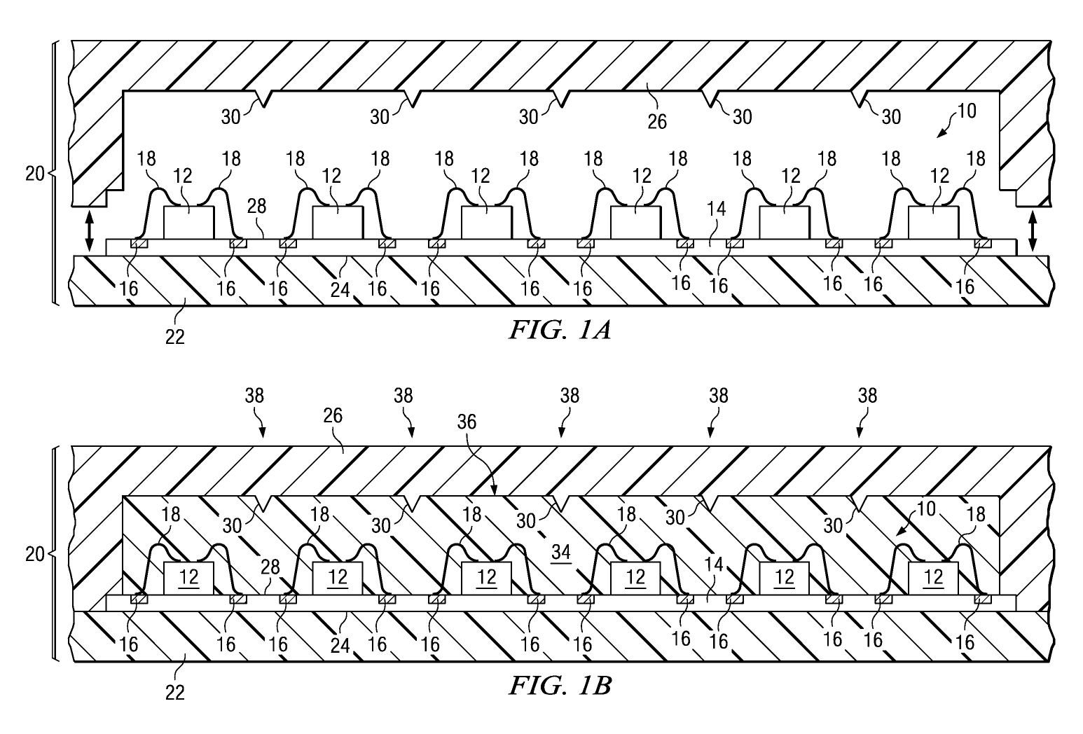

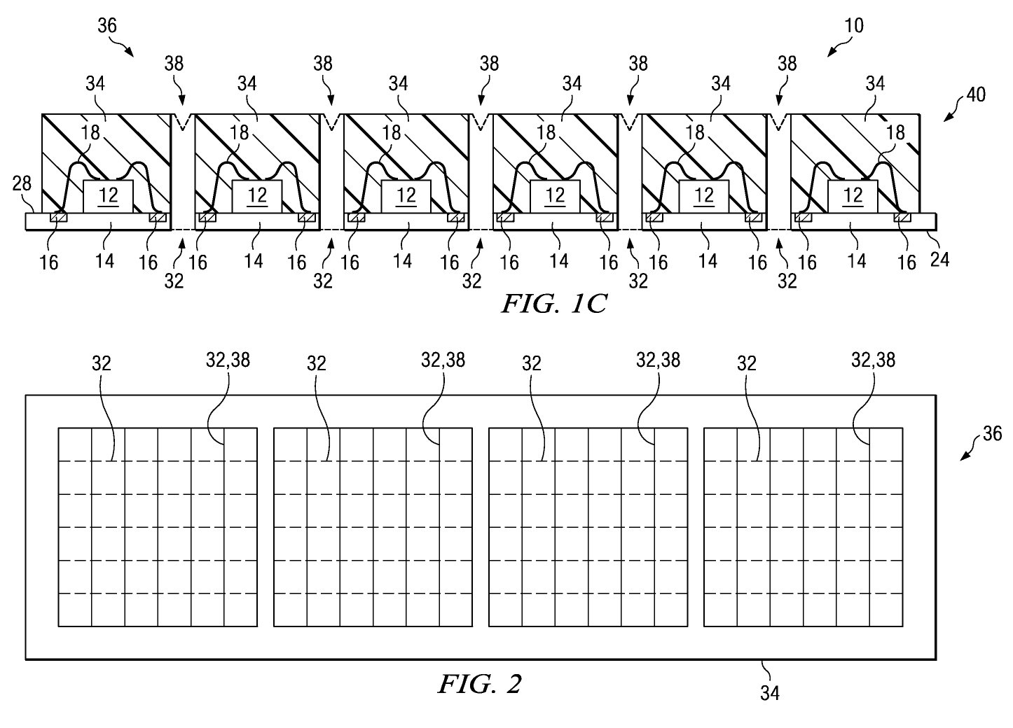

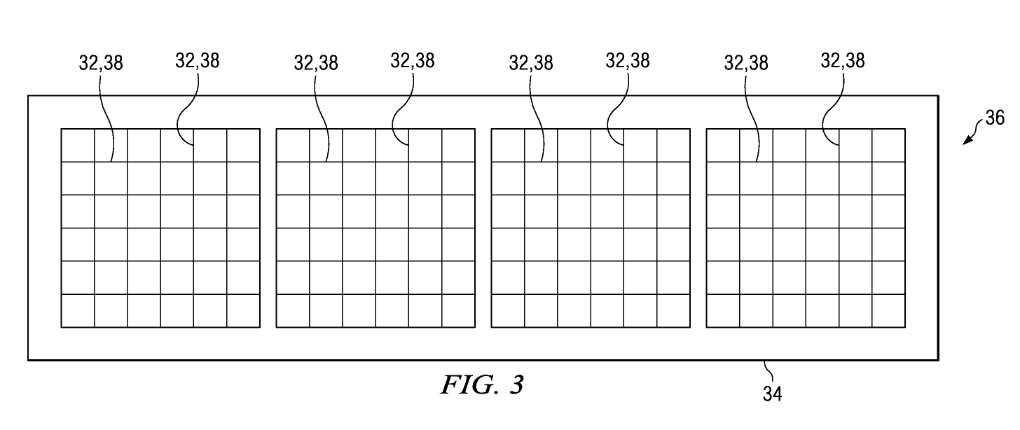

Now referring primarily to FIG. 1A, an array 10 is shown including chips 12 attached to a substrate 14. The chips 12 are arranged in rows and may be affixed to the substrate 14 and electrically coupled to bond pads 16 using bondwires 18 or surface connections (not shown) as known in the arts. The exact configuration of the chip and substrate combination in the array 10 is not crucial to the practice of invention. A mold 20 is provided, preferably including a base 22 for supporting the back surface 24 of the substrate 14, and a cap 26 for enclosing the substrate 14, the chip 12, and any other features present on the face 28 of the substrate such as the bond wires 18 and bond pads 16 shown. The mold cap 26 includes projections 30. The projections 30 are preferably in the form of ridges arranged in a regular pattern. For example, typical patterns include regularly spaced parallel ridges or a grid. Preferably, the ridges 30 are provided as an integral part of the inner surface of the mold cap 26. The ridges 30 are preferably positioned to coincide with the saw streets 32 ordinarily included in the array 10 design for the purpose of facilitating singulation, as shown for example in FIG. 3. The cross-sectional shape of the ridges 30, such as the pointed shape shown, is not absolutely critical to the practice of the invention, although shapes conducive to the molding process are preferred. For example, some degree of pointing or rounding, e.g. a “V” or “U” shape is believed to be desirable to facilitate later mold removal.

Now referring more particularly to FIG. 1B, the mold 20 and array 10 are positioned so that the array 10 is enclosed within the mold cap 26. Mold compound 34 is preferably introduced into the mold 20 using techniques known in the arts in order to encapsulate the array 10. When the mold compound 34 is sufficiently cured, the mold 20 is removed, releasing a block-molded array 36 including the chip/substrate array 10 encased within hardened mold compound 34. Due to the action of the projections 30, preferably ridges, mold compound 34 is excluded from selected areas during encapsulation to form a series of raised areas, preferably ditches 38, at the surface of the block-molded array 36. Preferably, the ditches 38 are arranged to correspond with at least some of the saw streets 32 provided in the chip/substrate array 10. As shown in FIG. 1C, the block-molded array 36 is preferably singulated along the saw streets 32, forming individual packages 40.

Those of ordinary knowledge and skill in the arts will appreciate that common types of mold compound generally have a tendency to shrink during curing. Thus, hardened blocks of mold compound tend to experience tensile stress that can lead to warpage. It should be appreciated that the ditches provided by the invention function to buffer, alleviate, or redirect tensile stress, reducing or eliminating block warpage. Preferably, the invention may be practiced using a modified mold cap with a traditional mold base, using traditional packaging techniques and materials with the modified mold cap.

The invention provides advantages including but not limited to increased process efficiency and yields due to decreased warpage. While the invention has been described with reference to certain illustrative embodiments, the methods and devices described are not intended to be construed in a limiting sense. Various modifications and combinations of the illustrative embodiments as well as other advantages and embodiments of the invention will be apparent to persons skilled in the art upon reference to the description and claims.

I claim:

1. A method for block-molded semiconductor device package manufacturing comprising the steps of:
providing an array of chips mounted on a substrate;
placing the chip and substrate array into a mold, the mold being configured for encapsulating the chip and substrate array and having projections for excluding mold compound from selected areas;
introducing mold compound into the mold and curing the mold compound, thereby encapsulating the chip and substrate array, forming a block-molded array having ditches formed by the exclusion of mold compound from selected areas;
removing the block-molded array from the mold; and
singulating individual semiconductor device packages from the block-molded array.

2. A method according to claim 1 wherein the chip and substrate array are provided with a plurality of saw streets, and wherein at least some of the ditches are formed in vertical alignment with saw streets.

3. A method according to claim 1 wherein the chip and substrate array are provided with a plurality of saw streets, and wherein all of the ditches are formed in vertical alignment with saw streets.

4. A method according to claim 1 wherein the ditches formed by the exclusion of mold compound from selected areas are substantially V-shaped in cross section.

5. A method according to claim 1 wherein the ditches formed by the exclusion of mold compound from selected areas are substantially U-shaped in cross section.

6. A method according to claim 1 wherein the ditches are formed in a regularly spaced parallel pattern.

7. A method according to claim 1 wherein the ditches are formed in a grid pattern.

8. A method according to claim 1 wherein the step of singulation is performed using sawing equipment.

9. A block mold for semiconductor device package manufacturing comprising:
a base configured for supporting an array of chips mounted on a substrate;
a cap configured for encapsulating the chip and substrate array, the cap further comprising projections for excluding mold compound from selected areas at the surface of the package.

10. A block mold according to claim 9 wherein the cap further comprises projections forming continuous ridges on the surface of the cap.

11. A block mold according to claim 9 wherein the cap further comprises projections arranged in a regular pattern on the surface of the cap.

12. A block mold according to claim 9 wherein the cap further comprises projections arranged in a grid pattern on the surface of the cap.

13. A block mold according to claim 9 wherein the cap further comprises projections forming ridges on the surface of the cap, wherein the ridges are substantially V-shaped in cross section.

14. A block mold according to claim 9 wherein the cap further comprises projections forming ridges on the surface of the cap, wherein the ridges are substantially U-shaped in cross section.

15. A block mold according to claim 9 wherein the cap further comprises projections arranged in a regular pattern on the surface of the cap, and wherein at least some of the projections are arranged for placement in vertical alignment with saw streets on an array of chips mounted on a substrate when the array is placed within the mold.

16. A block mold according to claim 9 wherein the cap further comprises projections arranged in a regular pattern on the surface of the cap, and wherein the projections are arranged for placement in vertical alignment with saw streets on an array of chips mounted on a substrate when the array is placed within the mold.
